(19) United States
(12) Patent Application Publication
(10) Pub. No.: US 2023/0037202 A1
(43) Pub. Date: Feb. 2, 2023

(54) POWER CONVERSION DEVICE

(71) Applicant: Panasonic Intellectual Property Management Co., Ltd., Osaka (JP)

(72) Inventors: Motohiko FUJIMURA, Osaka (JP); Hiroshi OGURA, Tokyo (JP); Yoshihiro KAWAKITA, Osaka (JP); Hidetoshi KITAURA, Osaka (JP)

(21) Appl. No.: 17/867,974

(22) Filed: Jul. 19, 2022

(30) Foreign Application Priority Data
Jul. 27, 2021 (JP) 2021-122381

(51) Int. Cl. H01R 12/71; H01R 4/28; H02M 3/04; H03F 3/45

(52) U.S. Cl. CPC H01R 12/716; H01R 4/28; H02M 3/04; H03F 3/45

(57) ABSTRACT

A power conversion device includes: circuit boards; at least one engagement member configured to engage a male engagement member with a female engagement member to allow the circuit boards to be electrically connected, the male engagement member being connected to one of the circuit boards and having a substantially flat plate-shaped insertion portion, the female engagement member being connected to another of the circuit boards and having first and second clamping portions disposed to face each other, and the engagement of the engagement members being made by clamping the insertion portion by the clamping portions; a differential amplifier configured to measure a voltage across the engagement member; an arithmetic unit configured to estimate a resistance value of the engagement member based on the measured voltage; and a power conversion circuit controller configured to perform notification on condition that the estimated resistance value exceeds a resistance threshold.

### CROSS-REFERENCE TO RELATED APPLICATIONS

This application is based upon and claims the benefit of priority from Japanese Patent Application No. 2021-122381, filed on Jul. 27, 2021, the entire contents of which are incorporated herein by reference.

### FIELD

Embodiments described herein relate generally to a power conversion device.

### BACKGROUND

Japanese Patent Application Laid-open No. 2000-014128 discloses a power supply device in which different boards are connected to each other by a conductive engagement member.

In the power supply device disclosed in Japanese Patent Application Laid-open No. 2000-014128, because a board has a high temperature due to a large current flowing through a circuit, thermal strain according to a linear expansion coefficient may occur in the engagement member, and unintended contact resistance may occur in the engagement member. In addition, in the use of the power supply device disclosed in Japanese Patent Application Laid-open No. 2000-014128 mounted on a vehicle, mechanical vibration might cause sliding of the engagement member. Repeated sliding of the engagement member accelerates scraping or oxidation of the contact surface, which may increase contact resistance of the engagement member. Furthermore, when the engagement member is exposed to a high temperature for a long period of time due to an operation of the power supply device for a long period of time, there is a possibility that a decrease in contact pressure due to stress relaxation of the engagement member would increase the contact resistance. The increase in the contact resistance of the engagement member might impair the electrical connection function of the power supply circuit.

Japanese Patent Application Laid-open No. 2000-014128 has no disclosure or suggestion regarding estimation of the change in an electrical characteristic or a physical change that can occur in such an engagement member.

An object of the present disclosure is to provide a power conversion device that has a connection structure in which different circuit boards are connected by a conductive engagement member and that is capable of estimating a change in an electrical characteristic of the engagement member.

### SUMMARY

A power conversion device according to the present disclosure includes a first component, a second component, at least one engagement member, a voltage measurer, a resistance value estimator, and a notifier. The at least one engagement member is configured to engage a male engagement member with a female engagement member to allow the first component and the second component to be electrically connected to each other, the male engagement member being connected to one of the first component and the second component and having a conductive and substantially flat plate-shaped insertion portion, the female engagement member being connected to another of the first component and the second component and having conductive first and second clamping portions disposed to face each other, and the engagement of the male engagement member and the female engagement member being made by clamping the insertion portion by the first and second clamping portions. The voltage measurer is configured to measure a voltage across the at least one engagement member. The resistance value estimator is configured to estimate a resistance value of the engagement member based on the voltage measured by the voltage measurer. The notifier is configured to perform notification on condition that the resistance value estimated by the resistance value estimator exceeds a resistance threshold.

### BRIEF DESCRIPTION OF THE DRAWINGS

FIG. 1 is a schematic cross-sectional view illustrating an example of a layered structure of a plurality of circuit boards constituting a power conversion circuit;

FIG. 2 is a schematic view illustrating an example of configurations and coupled states of engagement members in FIG. 1;

FIG. 3 is a block diagram illustrating an example of a schematic configuration of a power conversion device according to a first embodiment;

FIG. 4 is a flowchart illustrating an example of a flow of processing performed by the power conversion device according to the first embodiment;

FIG. 5 is a block diagram illustrating an example of a schematic configuration of a power conversion device according to a modification of the first embodiment;

FIG. 6 is a flowchart illustrating an example of a flow of processing performed by the power conversion device according to the modification of the first embodiment;

FIG. 7 is a block diagram illustrating an example of a schematic configuration of a power conversion device according to a second embodiment;

FIG. 8 is a flowchart illustrating an example of a flow of processing performed by the power conversion device according to the second embodiment;

FIG. 9 is a block diagram illustrating an example of a schematic configuration of a power conversion device according to a modification of the second embodiment;

FIG. 10 is a block diagram illustrating an example of a schematic configuration of a power conversion device according to a third embodiment;

FIG. 11 is a flowchart illustrating an example of a flow of processing performed by the power conversion device according to the third embodiment;

FIG. 12 is a block diagram illustrating an example of a schematic configuration of a power conversion device according to a fourth embodiment;

FIG. 13 is a diagram illustrating an example of a circuit configuration of measuring temperature by a thermistor;

FIG. 14 is a flowchart illustrating an example of a flow of processing performed by the power conversion device according to the fourth embodiment;

FIG. 15 is a block diagram illustrating an example of a schematic configuration of a power conversion device according to a fifth embodiment;

FIG. 16 is a diagram illustrating an example of a circuit configuration of measuring strain by a strain gauge;

FIG. 17 is a flowchart illustrating an example of a flow of processing performed by the power conversion device according to the fifth embodiment;

FIG. 18 is a block diagram illustrating an example of a schematic configuration of a power conversion device according to a sixth embodiment; and

FIG. 19 is a flowchart illustrating an example of a flow of processing performed by the power conversion device according to the sixth embodiment.

### DETAILED DESCRIPTION

### First Embodiment

Hereinafter, various embodiments of a power conversion device according to the present disclosure will be described with reference to the drawings.

Board Configuration of Power Conversion Circuit

First, the board configurations of power conversion circuits according to the entire embodiments below will be described. An example of the power conversion circuit is an in-vehicle charger that is mounted on an electric vehicle or the like, converts alternating current (AC) power supplied from a power supply (external power supply) into direct current (DC) power of a predetermined voltage, and outputs the converted DC power to a battery such as a lithium-ion battery. Such a power conversion circuit includes a plurality of circuit boards including circuit configurations such as a DC/DC converter and an inverter. The DC/DC converter converts a direct current (DC) voltage into another DC voltage to generate a DC voltage suitable for each electronic device. The inverter generates AC power having different frequencies from DC or AC power.

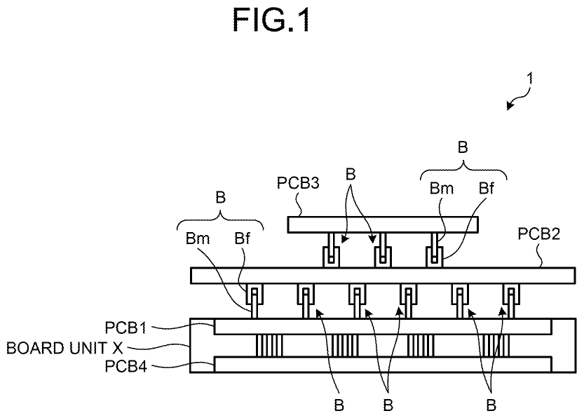

A board configuration of a power conversion circuit included in a power conversion device will be described with reference to FIG. 1. FIG. 1 is a schematic cross-sectional view illustrating an example of a layered structure of a plurality of circuit boards constituting a power conversion circuit. Of a plurality of circuit boards included in a power conversion circuit 1, FIG. 1 illustrates, in particular, a first board PCB1, a second board PCB2, a third board PCB3, and a fourth board PCB4.

The first board PCB1, the second board PCB2, the third board PCB3, and the fourth board PCB4 are each a board, generally referred to as a printed circuit board (PCB). The printed circuit board is, for example, a metal board formed using an aluminum alloy or a copper alloy as a base material. By bringing a part of the aluminum alloy or the copper alloy of the printed circuit board into contact with a water-cooled stand in a heat-exchangeable manner, it is possible to suppress a temperature increase in electronic components mounted on the printed circuit board. By using a printed circuit board using metal as a base material, it is possible to improve the cooling efficiency as compared with the case of using a printed circuit board using resin as a base material.

The first board PCB1 is coupled to the second board PCB2 by a plurality of pairs of engagement members B. In the following description, the plurality of pairs of engagement members B will be referred to as pairs of engagement members B in some cases. In addition, the pair of engagement members B are also referred to as an engagement unit in some cases. The first board PCB1 is electrically connected to the second board PCB2, and outputs power corresponding to the power supplied from the second board PCB2 to a battery and the like. The first board PCB1 is electrically connected to the fourth board PCB4 to constitute a board unit X. On a surface of the first board PCB1 facing the second board PCB2, a plurality of male engagement members Bm is disposed.

The second board PCB2 is coupled to each of the first board PCB1 and the third board PCB3 by a plurality of pairs of engagement members B. The second board PCB2 is electrically connected to each of the first board PCB1 and the third board PCB3, and outputs power corresponding to the power supplied from the third board PCB3 to the first board PCB1. On a surface of the second board PCB2 facing the first board PCB1 and on a surface of the second board PCB2 facing the third board PCB3, a plurality of female engagement members Bf is disposed. That is, the male engagement member Bm and the female engagement member Bf are engaged with each other to form the engagement member B.

The third board PCB3 is coupled to the second board PCB2 by a plurality of pairs of engagement members B. The third board PCB3 is electrically connected to an external power supply, for example, and receives power from the external power supply. A plurality of male engagement members Bm is arranged on a surface of the third board PCB3 on the second board PCB2 side.

Although the embodiment is a case where a plurality of male engagement members Bm is disposed on the first board PCB1 and the third board PCB3, and a plurality of female engagement members Bf is disposed on both surfaces of the second board PCB2, but the layout of engagement members is not limited thereto. For example, a plurality of female engagement members Bf may be disposed on the first board PCB1 and the third board PCB3, and a plurality of male engagement members Bm may be disposed on both main surfaces of the second board PCB2.

Furthermore, for example, a plurality of male engagement members Bm may be disposed on one surface of the second board PCB2, and a plurality of female engagement members Bf may be disposed on the other surface of the second board PCB2.

Furthermore, for example, in each of the first board PCB1, the second board PCB2, and the third board PCB3, a plurality of male engagement members Bm and a plurality of female engagement members Bf may be disposed on one surface.

In addition, the first board PCB1 and the fourth board PCB4 of the board unit X can also be coupled to each other by a plurality of pairs of engagement members B according to the embodiment. In short, the connection structure by the engagement member B may be applied to coupling between boards in a board unit such as the board unit X, may be applied to coupling between board units, or may be applied to coupling between a board unit and a board outside the board unit.

Configuration of Engagement Member

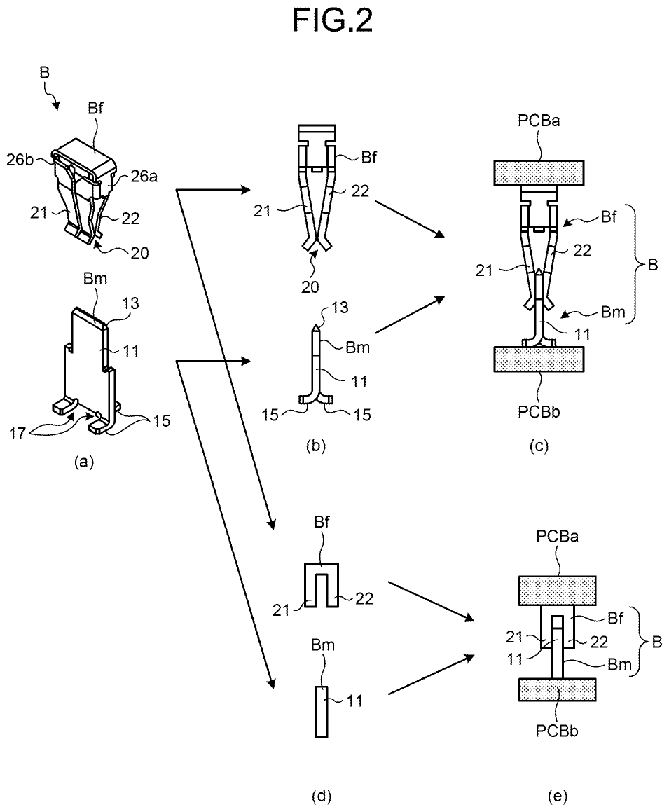

FIG. 2 is a schematic view illustrating an example of configurations and coupled states of engagement members in FIG. 1. (a) of FIG. 2 illustrates an example of configurations of the male engagement member Bm and the female engagement member Bf. (b) of FIG. 2 illustrates an example of a side view of the male engagement member Bm and the female engagement member Bf. (c) of FIG. 2 illustrates an example of a side view of a state in which the male engagement member Bm and the female engagement member Bf are engaged with each other. (d) of FIG. 2 illustrates an example of a symbol as a simple representation of the male engagement member Bm and the female engagement member Bf. (e) of FIG. 2 illustrates an example of a symbol as a simple representation of a state in which the male engagement member Bm and the female engagement member Bf are engaged with each other.

As illustrated in (a) of FIG. 2, the male engagement member Bm is a conductive blade-shaped connector (plug) on the insertion side. The male engagement member Bm includes an insertion portion 11 having a substantially flat plate shape. A distal end portion 13 of the insertion portion 11 is chamfered and has a smaller thickness toward the distal end side. This facilitates insertion of the insertion portion 11 into a receiving portion 20 of the female engagement member Bf. An end of the insertion portion 11 opposite to the distal end portion 13 is provided with a connecting portion 15. The connecting portion 15 is a portion formed by dividing the end on the opposite side of the distal end portion 13 into three portions by gaps 17. The connecting portion 15 is alternately bent in a direction substantially perpendicular to the insertion portion 11 to function as a joint when the male engagement member Bm is soldered to the board. The insertion portion 11 and the connecting portion 15 are formed by a bending process of a single metal plate, for example. The number of divisions of the connecting portion 15 is not limited to 3, and any number of divisions can be set. For example, the larger the width of the insertion portion 11, the larger the number of divisions would be allowable.

The female engagement member Bf is a conductive connector (receptacle) on the side of receiving insertion. The female engagement member Bf clamps the insertion portion 11 of the male engagement member Bm inserted into the receiving portion 20. The female engagement member Bf is formed by a bending process of a single metal plate, for example. The female engagement member Bf has a substantially Y-shape in which the distal end side is open when viewed from the side surface side, specifically, the side of a first base 26a or a second base 26b.

More specifically, the female engagement member Bf includes a first clamping portion 21 and a second clamping portion 22. The first clamping portion 21 and the second clamping portion 22 are disposed to face each other. The surface of the first clamping portion 21 facing the second clamping portion 22 and the surface of the second clamping portion 22 facing the first clamping portion 21 form the receiving portion 20. That is, the first clamping portion 21 and the second clamping portion 22 face each other across the receiving portion 20. Using the first clamping portion 21 and the second clamping portion 22, the female engagement member Bf clamps the insertion portion 11 of the male engagement member Bm inserted into the receiving portion 20.

More specifically, the insertion portion 11 of the male engagement member Bm mounted on a circuit board PCB is inserted into the receiving portion 20 of the female engagement member Bf. At this time, the insertion portion 11 is inserted so as to expand the interval between the first clamping portion 21 and the second clamping portion 22 while being in contact with the first clamping portion 21 and the second clamping portion 22. As illustrated in (c) of FIG. 2, the female engagement member Bf clamps the insertion portion 11 of the male engagement member Bm inserted between the first clamping portion 21 and the second clamping portion 22, whereby a circuit board PCBa on which the female engagement member Bf is disposed and a circuit board PCBb on which the male engagement member Bm is disposed are electrically connected to each other. Note that the length of inserting the male engagement member Bm into the female engagement member Bf, that is, an insertion height, can be appropriately set according to conditions such as a distance between the boards to be coupled. Here, the circuit board PCBa and the circuit board PCBb refer to two different boards among the first board PCB1, the second board PCB2, the third board PCB3, and the fourth board PCB4 illustrated in FIG. 1.

The male engagement member Bm and the female engagement member Bf are each formed of a metal material. As an example, the male engagement member Bm and the female engagement member Bf are formed of a conductive metal such as copper, brass, nickel, or aluminum.

In addition, conductor plating is applied to some or all of the surfaces of the male engagement member Bm and the female engagement member Bf. Examples of the conductor plating that can be appropriately used include tin plating, silver plating, and gold plating.

Note that the male engagement member Bm and the female engagement member Bf are to be simply represented by symbols illustrated in (d) and (e) of FIG. 2. The male engagement member Bm and the female engagement member Bf illustrated in FIG. 1 are also expressed using this symbol.

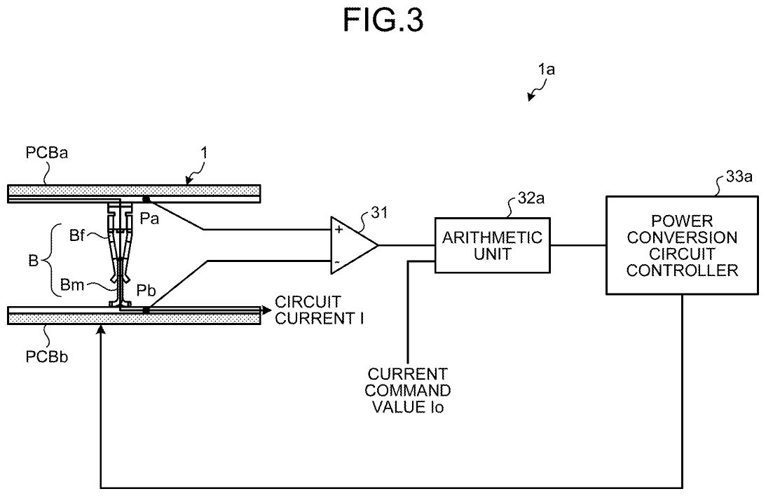

When the engagement members B (the male engagement member Bm and the female engagement member Bf) having such a structure are electrically connected between different boards and operated in a vehicle-mounted environment, for example, there is a possibility, as described above, that the contact resistance of the engagement member B will increase due to the influence of heat generated by the operation of the power conversion circuit 1 or the influence of sliding of the contact between the male engagement member Bm and the female engagement member Bf due to mechanical vibration or strain of the circuit board. A power conversion device 1a (FIG. 3) of the present embodiment performs estimation and notification of such a change in an electrical characteristic of the engagement member B.

Configuration of Power Conversion Device

The configuration of the power conversion device 1a according to the first embodiment will be described with reference to FIG. 3. FIG. 3 is a block diagram illustrating an example of a schematic configuration of the power conversion device 1a according to the first embodiment.

The power conversion device 1a has a configuration in which a differential amplifier 31, an arithmetic unit 32a, and a power conversion circuit controller 33a have been added to the power conversion circuit 1 (FIG. 1) described above.

The differential amplifier 31 is connected across, that is, between points on both ends of the engagement member B electrically connecting different boards of the power conversion circuit 1, for example, between a point Pa of the conducting portion of the circuit board PCBa and a point Pb of the conducting portion of the circuit board PCBb. That is, the point Pa and the point Pb are electrically connected to allow the passage of a circuit current I. The differential amplifier 31 measures a voltage between the point Pa and the point Pb, that is, a voltage e across the engagement member B. Note that the circuit board PCBa is an example of a first component in the present disclosure. The circuit board PCBb is an example of a second component in the present disclosure. Furthermore, the differential amplifier 31 is an example of a voltage measurer in the present disclosure.

Note that, of the boards constituting the power conversion circuit 1, the circuit board PCBa and the circuit board PCBb may be any board as long as the board is electrically connected by the engagement member B. For example, the circuit board PCBa may be the third board PCB3 while the circuit board PCBb may be the second board PCB2; or the circuit board PCBa may be the second board PCB2 while the circuit board PCBb may be the first board PCB1.

The arithmetic unit 32a estimates a resistance value r of the engagement member B based on the voltage e measured by the differential amplifier 31. The arithmetic unit 32a is an example of a resistance value estimator in the present disclosure. Specifically, the arithmetic unit 32a applies A/D conversion on the voltage e measured by the differential amplifier 31 to be converted into a digital value. Subsequently, the arithmetic unit 32a estimates the resistance value r of the engagement member B based on the voltage e converted to the digital value and based on a current command value Io flowing between the circuit board PCBa and the circuit board PCBb. The resistance value r of the engagement member B is estimated by dividing the voltage e measured by the differential amplifier 31 by the current command value Io. The current command value Io can be specified by reading a control parameter of the power conversion circuit controller 33a.

The power conversion circuit controller 33a performs notification on condition that the resistance value r of the engagement member B estimated by the arithmetic unit 32a exceeds a resistance threshold Rth. The notification may be performed by using any method, and for example, the power conversion circuit controller 33a sets the current command value of the power conversion circuit 1 to zero to stop the power conversion operation. The value of the resistance threshold Rth is set in advance based on a result of a prior experiment or the like. Note that the power conversion circuit controller 33a is an example of a notifier in the present disclosure.

In FIG. 3, a method of implementation of each component is not limited. That is, the differential amplifier 31, the arithmetic unit 32a, and the power conversion circuit controller 33a may be implemented separately, or may be implemented by one IC such as a digital signal processor (DSP).

Flow of Processing Performed by Power Conversion Device of First Embodiment

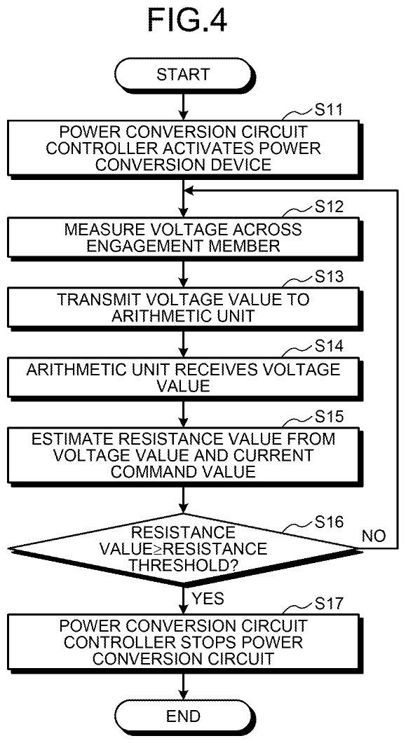

A flow of processing performed by the power conversion device 1a will be described with reference to FIG. 4. FIG. 4 is a flowchart illustrating an example of a flow of processing performed by the power conversion device 1a according to the first embodiment.

The power conversion circuit controller 33a activates the power conversion device 1a (Step S11).

The differential amplifier 31 measures the voltage e across the engagement member B (Step S12).

The differential amplifier 31 transmits the measured voltage e to the arithmetic unit 32a (Step S13).

The arithmetic unit 32a receives the voltage e from the differential amplifier 31 (Step S14).

The arithmetic unit 32a estimates the resistance value r of the engagement member B from the voltage e and the current command value Io (Step S15).

The power conversion circuit controller 33a determines whether the resistance value r is the resistance threshold Rth or more (Step S16). When it is determined that the resistance value r is the resistance threshold Rth or more (Step S16: Yes), the processing proceeds to Step S17. In contrast, when it is not determined that the resistance value r is the resistance threshold Rth or more (Step S16: No), the processing returns to Step S12.

When it is determined in Step S16 that the resistance value r is the resistance threshold Rth or more, the power conversion circuit controller 33a stops the operation of the power conversion circuit 1 (Step S17).

The power conversion device 1a may include a display device, an indicator, a buzzer, or the like that outputs information indicating that the power conversion circuit controller 33a has stopped the operation of the power conversion circuit 1.

Although the power conversion device 1a estimates the resistance value r of one engagement member B, the power conversion device 1a may estimate the resistance values r of a plurality of the engagement members B. When estimating the resistance values r of the plurality of engagement members B, the power conversion device 1a desirably controls the operation of the power conversion circuit 1 based on the highest resistance value r estimated.

Operational Effect of First Embodiment

As described above, the power conversion device 1a according to the first embodiment includes: the circuit board PCBa (first component); the circuit board PCBb (second component); at least one engagement member B configured to engage the male engagement member Bm that is connected to either one of the circuit board PCBa or the circuit board PCBb and that has the conductive and substantially flat plate-shaped insertion portion 11 with the female engagement member Bf that is connected to the other of the circuit board PCBa and the circuit board PCBb and that has the first clamping portion 21 and the second clamping portion 22 having conductivity and disposed to face each other, the engagement of the male engagement member Bm and the female engagement member Bf made by clamping the insertion portion 11 by the first clamping portion 21 and the second clamping portion 22 so as to allow the circuit board PCBa and the circuit board PCBb to be electrically connected to each other; a differential amplifier 31 (voltage measurer) that measures the voltage e across the at least one engagement member B; an arithmetic unit 32a (resistance value estimator) that estimates the resistance value r of the engagement member B based on the voltage e measured by the differential amplifier 31; and the power conversion circuit controller 33a (notifier) that performs notification on condition that the resistance value r estimated by the arithmetic unit 32a exceeds the resistance threshold Rth. This makes it possible to easily and reliably estimate the change in an electrical characteristic of the engagement member B.

Furthermore, in the power conversion device 1a according to the first embodiment, the arithmetic unit 32a (resistance value estimator) estimates the resistance value r of the engagement member B based on the voltage e measured by the differential amplifier 31 (voltage measurer) and the current command value Io flowing between the circuit board PCBa (first component) and the circuit board PCBb (second component). This makes it possible to estimate the resistance value r of the engagement member B with simple arithmetic operations.

In addition, in the power conversion device 1a according to the first embodiment, the power conversion circuit controller 33a (notifier) stops energization to the power conversion device 1a on condition that the resistance value r estimated by the arithmetic unit 32a (resistance value estimator) exceeds the resistance threshold Rth. This makes it possible to prevent the power conversion device 1a from being damaged because of a change in an electrical characteristic of the engagement member B.

Modification of First Embodiment

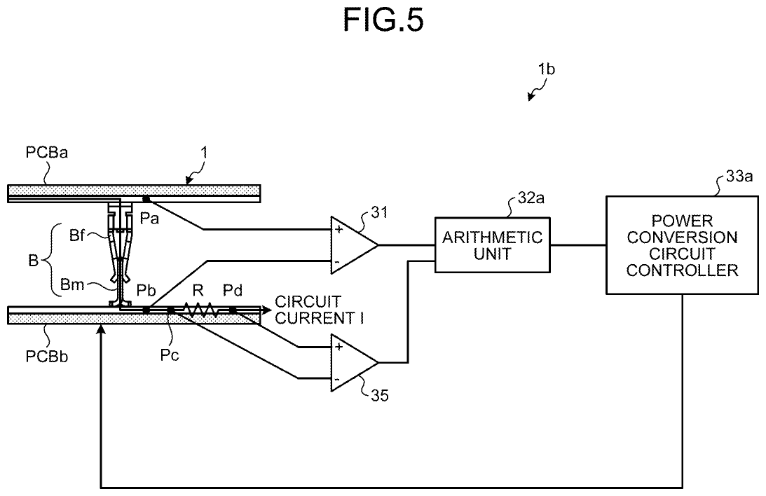

A configuration of a power conversion device lb as a modification of the first embodiment will be described with reference to FIG. 5. FIG. 5 is a block diagram illustrating an example of a schematic configuration of a power conversion device according to a modification of the first embodiment. Since the configuration of the main part of the power conversion device 1b is similar to the configuration of the power conversion device 1a, only the difference will be described.

The power conversion device 1b estimates the resistance value r of the engagement member B from the voltage e measured by the differential amplifier 31 and the circuit current I flowing between the circuit board PCBa and the circuit board PCBb via the engagement member B.

The circuit current I is calculated in the arithmetic unit 32a by dividing a voltage ea (between both ends Pc and Pd) across a shunt resistance R inserted into a current path formed between the circuit board PCBa and the circuit board PCBb via the engagement member B by a resistance value ra of the shunt resistance R. The voltage ea across the shunt resistance R is measured by the differential amplifier 35. The differential amplifier 35 is an example of a current measurer in the present disclosure. Although the example of FIG. 5 is a case where the shunt resistance R is inserted into the current path of the circuit board PCBb, the shunt resistance R may be inserted into the current path of the circuit board PCBa. Instead of the shunt resistance R, a current measuring element such as a current transformer or a Hall sensor may be inserted.

Furthermore, the arithmetic unit 32a converts the voltage e measured by the differential amplifier 31 and the circuit current I into digital values by A/D conversion. Subsequently, the arithmetic unit 32a estimates the resistance value r of the engagement member B from the voltage e and the circuit current I each converted to the digital value.

That is, the power conversion device 1b is different from the power conversion device 1a of the first embodiment in that the resistance value r of the engagement member B is estimated using the circuit current I actually flowing through the circuit board instead of using the current command value Io.

The configuration of controlling energization to the power conversion device 1b based on the estimated resistance value r is similar to the case of the power conversion device 1a.

Flow of Processing Performed by Power Conversion Device According to Modification of First Embodiment

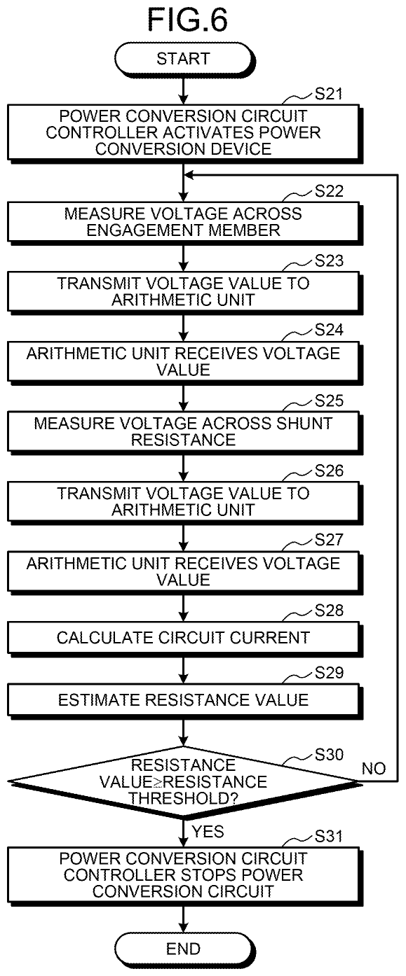

A flow of processing performed by the power conversion device 1b will be described with reference to FIG. 6. FIG. 6 is a flowchart illustrating an example of a flow of processing performed by the power conversion device 1b according to a modification of the first embodiment.

The power conversion circuit controller 33a activates the power conversion device 1b (Step S21).

The differential amplifier 31 measures the voltage e across the engagement member B (Step S22).

The differential amplifier 31 transmits the measured voltage e to the arithmetic unit 32a (Step S23).

The arithmetic unit 32a receives the voltage e from the differential amplifier 31 (Step S24).

The differential amplifier 35 measures the voltage ea across the shunt resistance R (Step S25).

The differential amplifier 35 transmits the measured voltage ea to the arithmetic unit 32a (Step S26).

The arithmetic unit 32a receives the voltage ea from the differential amplifier 35 (Step S27).

The arithmetic unit 32a calculates the circuit current I (Step S28).

The arithmetic unit 32a estimates the resistance value r of the engagement member B from the voltage e and the circuit current I (Step S29).

The power conversion circuit controller 33a determines whether the resistance value r is the resistance threshold Rth or more (Step S30). When it is determined that the resistance value r is the resistance threshold Rth or more (Step S30: Yes), the processing proceeds to Step S31. In contrast, when it is not determined that the resistance value r is the resistance threshold Rth or more (Step S30: No), the processing returns to Step S22.

When it is determined in Step S30 that the resistance value r is the resistance threshold Rth or more, the power conversion circuit controller 33a stops the operation of the power conversion circuit 1 (Step S31).

Operational Effect of Modification of First Embodiment

As described above, the power conversion device 1b according to the modification of the first embodiment further includes the differential amplifier 35 (current measurer) that measures the circuit current I flowing through the engagement member B, and the arithmetic unit 32a (resistance value estimator) estimates the resistance value r of the engagement member B based on the voltage e measured by the differential amplifier 31 (voltage measurer) and the circuit current I measured by the differential amplifier 35. This makes it possible to easily and reliably estimate the change in an electrical characteristic of the engagement member B.

### Second Embodiment

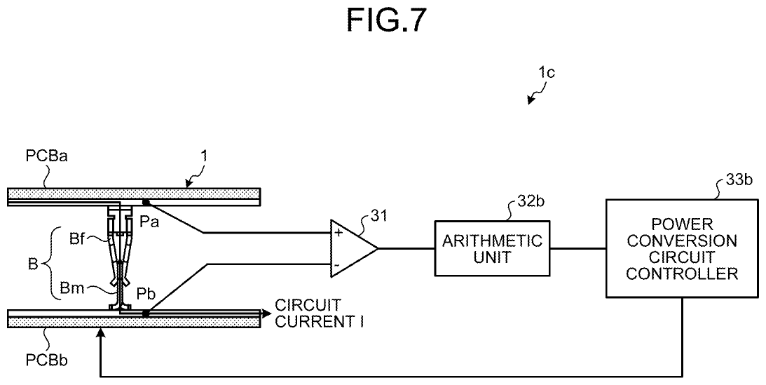

Next, a configuration of a power conversion device lc according to a second embodiment will be described with reference to FIG. 7. FIG. 7 is a block diagram illustrating an example of a schematic configuration of the power conversion device 1c according to the second embodiment.

The power conversion device 1c estimates the resistance value r of the engagement member B based on the voltage e measured by the differential amplifier 31.

The power conversion device 1c includes a power conversion circuit 1, a differential amplifier 31, an arithmetic unit 32b, and a power conversion circuit controller 33b.

The arithmetic unit 32b performs A/D conversion on the voltage e measured by the differential amplifier 31 to convert the voltage e into a digital value.

The power conversion circuit controller 33b performs notification on condition that the voltage e converted into the digital value exceeds a voltage threshold eth. The voltage threshold eth is a voltage across the engagement member B estimated as an integrated value of a maximum current Imax assumed to flow through the engagement member B and a resistance value rp assumed at occurrence of an abnormality in the engagement member B, for example. Note that the power conversion circuit controller 33b is an example of a notification means in the present disclosure.

When the voltage e exceeds the voltage threshold eth, the power conversion circuit controller 33b sets the current command value of the power conversion circuit 1 to zero and stops the power conversion operation.

Flow of Processing Performed by Power Conversion Device of Second Embodiment

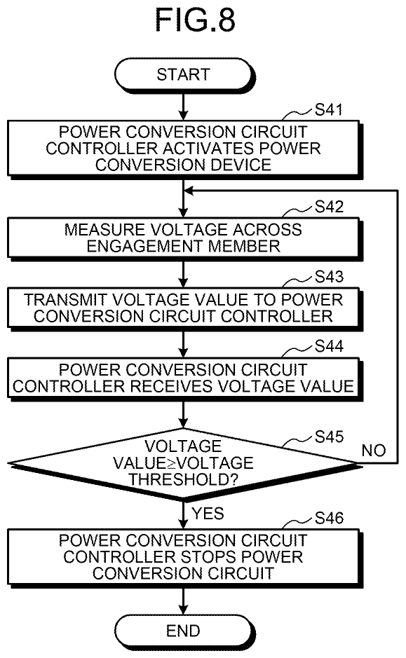

A flow of processing performed by the power conversion device 1c will be described with reference to FIG. 8. FIG. 8 is a flowchart illustrating an example of a flow of processing performed by the power conversion device 1c according to the second embodiment.

The power conversion circuit controller 33b activates the power conversion device 1c (Step S41).

The differential amplifier 31 measures the voltage e across the engagement member B (Step S42).

The arithmetic unit 32b converts the voltage e measured by the differential amplifier 31 into a digital value and transmits the digital value to the power conversion circuit controller 33b (Step S43).

The power conversion circuit controller 33b receives the voltage e converted into a digital value (Step S44).

The power conversion circuit controller 33b determines whether the voltage e is the voltage threshold eth or more (Step S45). When it is determined that the voltage e is the voltage threshold eth or more (Step S45: Yes), the processing proceeds to Step S46. In contrast, when it is not determined that the voltage e is the voltage threshold eth or more (Step S45: No), the processing returns to Step S42.

When it is determined in Step S45 that the voltage e is the voltage threshold eth or more, the power conversion circuit controller 33b stops the operation of the power conversion circuit 1 (Step S46).

### Operational Effect of Second Embodiment

As described above, the power conversion device 1c according to the second embodiment includes: the circuit board PCBa (first component); the circuit board PCBb (second component); at least one engagement member B configured to engage the male engagement member Bm that is connected to either one of the circuit board PCBa or the circuit board PCBb and that has the conductive and substantially flat plate-shaped insertion portion 11 with the female engagement member Bf that is connected to the other of the circuit board PCBa and the circuit board PCBb and that has the first clamping portion 21 and the second clamping portion 22 having conductivity and disposed to face each other, the engagement of the male engagement member Bm and the female engagement member Bf made by clamping the insertion portion 11 by the first clamping portion 21 and the second clamping portion 22 so as to allow the circuit board PCBa and the circuit board PCBb to be electrically connected to each other; a differential amplifier 31 (voltage measurer) that measures the voltage e across the engagement member B; and the power conversion circuit controller 33b (notifier) that performs notification on condition that the voltage e measured by the differential amplifier 31 exceeds the voltage threshold eth. This makes it possible to simply and reliably estimate the change in an electrical characteristic of the engagement member B.

In addition, in the power conversion device 1c according to the second embodiment, the voltage threshold eth is a voltage across the engagement member B when the maximum current Imax estimated to flow through the power conversion device 1c flows through the engagement member B in a case where the engagement member B is assumed to have a predetermined reference resistance value. This makes it possible to easily and reliably estimate the change in an electrical characteristic of the engagement member B.

In addition, in the power conversion device 1c according to the second embodiment, the power conversion circuit controller 33b (notifier) stops the power conversion device 1c on condition that the voltage e measured by the differential amplifier 31 (voltage measurer) exceeds the voltage threshold eth. This makes it possible to prevent the power conversion device 1c from being damaged because of a change in an electrical characteristic of the engagement member B.

Modification of Second Embodiment

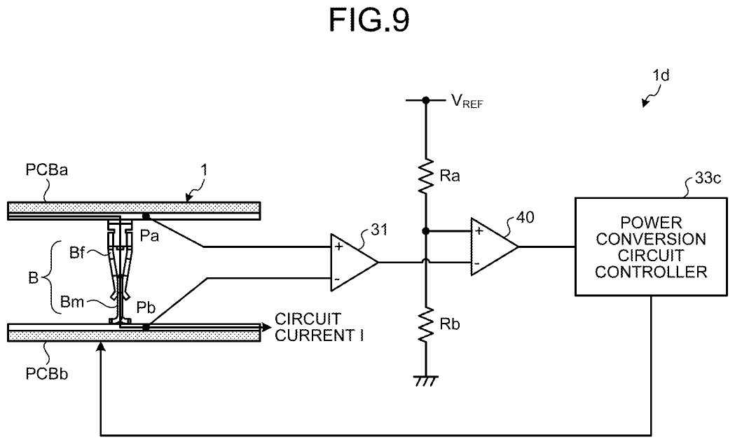

A configuration of a power conversion device 1d as a modification of the second embodiment will be described with reference to FIG. 9. FIG. 9 is a block diagram illustrating an example of a schematic configuration of the power conversion device 1d according to a modification of the second embodiment.

The comparison between the voltage e and the voltage threshold eth has been performed by software in the power conversion device 1c using the power conversion circuit controller 33b. However, this comparison is executed by hardware in the power conversion device 1d.

The power conversion device 1d includes a power conversion circuit 1, a differential amplifier 31, a differential amplifier 40, and a power conversion circuit controller 33c.

The differential amplifier 40 acts as a comparator (comparison device) that compares a voltage corresponding to the voltage threshold eth generated by dividing a voltage V_{REF} by resistors Ra and Rb with the voltage e across the engagement member B measured by the differential amplifier 31. The differential amplifier 40 outputs a High level when the voltage threshold eth is larger than the voltage e. The differential amplifier 40 outputs a Low level when the voltage threshold eth is smaller than the voltage e.

The power conversion circuit controller 33c performs notification on condition that the output of the differential amplifier 40 is at the Low level. The notification may be performed by using any method, and for example, it is allowable to set the current command value of the power conversion circuit 1 to zero to stop the power conversion operation. Note that the power conversion circuit controller 33c is an example of a notifier in the present disclosure.

The processing performed by the power conversion device 1d is implemented by hardware of the processing performed by the power conversion device 1c described above. Since the flow of the processing is similar to the processing of the power conversion device 1c, the description using the flowchart is omitted.

### Third Embodiment

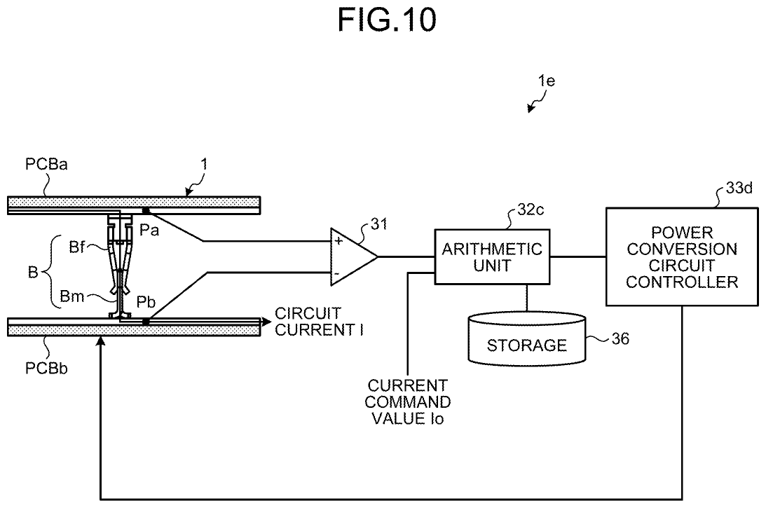

Next, a configuration of a power conversion device 1e according to a third embodiment will be described with reference to FIG. 10. FIG. 10 is a block diagram illustrating an example of a schematic configuration of the power conversion device 1e according to third embodiment.

The power conversion device 1e includes a power conversion circuit 1, a differential amplifier 31, an arithmetic unit 32c, a power conversion circuit controller 33d, and a storage 36.

The functions of the power conversion circuit 1 and the differential amplifier 31 are as described above.

The arithmetic unit 32c estimates the resistance value r of the engagement member B based on the voltage e measured by the differential amplifier 31. The arithmetic unit 32c is an example of a resistance value estimator in the present disclosure. Specifically, the arithmetic unit 32a applies A/D conversion on the voltage e measured by the differential amplifier 31 to be converted into a digital value. Subsequently, the arithmetic unit 32c estimates the resistance value r of the engagement member B based on the voltage e converted to the digital value and based on a current command value Io flowing between the circuit board PCBa and the circuit board PCBb. In addition, the arithmetic unit 32c stores the estimated resistance value r in the storage 36.

The storage 36 stores the resistance value r estimated by the arithmetic unit 32c in association with information specifying the time when the resistance value r is estimated. The storage 36 is, for example, non-volatile memory such as flash memory, a hard disk drive (HDD), or the like. The storage 36 may be separated from the arithmetic unit 32c or the power conversion circuit controller 33d, or may be integrated using one IC such as a DSP. The storage 36 is an example of a resistance value storage unit in the present disclosure.

The power conversion circuit controller 33d reads the resistance value r stored in the storage 36 and analyzes a change state of the resistance value r. Specifically, the power conversion circuit controller 33d performs notification on condition that an increase amount of the resistance value r stored in the storage 36 exceeds a resistance increase amount threshold Rith. The change state of the resistance value r is, for example, a difference value of the resistance value r at a predetermined time interval stored in the storage 36. The notification may be performed by any method, and may be performed by a display device, an indicator, a buzzer, or example. In addition, the value of the resistance increase amount threshold Rith is preset based on a result of a prior experiment or the like. Note that the power conversion circuit controller 33d is an example of a notifier in the present disclosure.

Flow of Processing Performed by Power Conversion Device of Third Embodiment

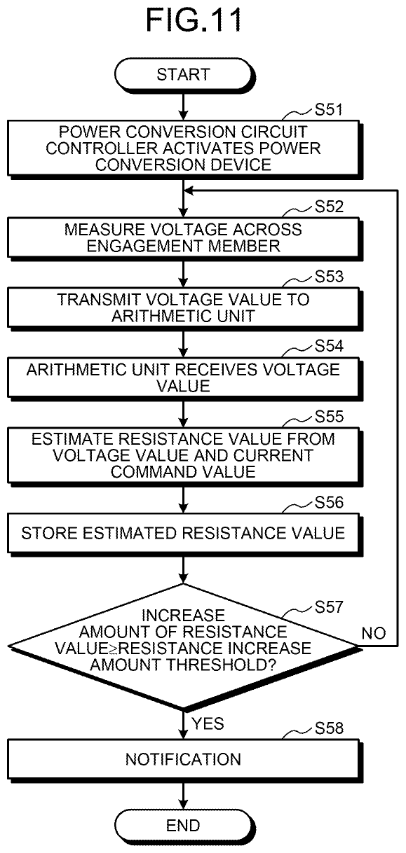

A flow of processing performed by the power conversion device 1e will be described with reference to FIG. 11. FIG. 11 is a flowchart illustrating an example of a flow of processing performed by the power conversion device 1e according to the third embodiment.

The power conversion circuit controller 33d activates the power conversion device 1e (Step S51).

The differential amplifier 31 measures the voltage e across the engagement member B (Step S52).

The differential amplifier 31 transmits the measured voltage e to the arithmetic unit 32c (Step S53).

The arithmetic unit 32c receives the voltage e from the differential amplifier 31 (Step S54).

The arithmetic unit 32c estimates the resistance value r of the engagement member B from the voltage e and the current command value Io (Step S55).

The arithmetic unit 32c stores the estimated resistance value r in the storage 36 in association with the time at which the resistance value r is estimated (Step S56).

The power conversion circuit controller 33d determines whether the increase amount of the resistance value r read from the storage 36 is the resistance increase amount threshold Rith or more (Step S57). When it is determined that the increase amount of the resistance value r is the resistance increase amount threshold Rith or more (Step S57: Yes), the processing proceeds to Step S58. In contrast, when it is not determined that the increase amount of the resistance value r is the resistance increase amount threshold Rith or more (Step S57: No), the processing returns to Step S52.

When it is determined in Step S56 that the increase amount of the resistance value r is the resistance increase amount threshold Rith or more, the power conversion circuit controller 33d performs notification (Step S58).

Note that, regarding the power conversion device 1c (FIG. 7) described in the second embodiment, it is also allowable to provide a power conversion device 1ea (not illustrated) that stores the voltage e measured by the differential amplifier 31 (voltage measurer) in the storage 36 together with the time at which the voltage e is measured, and performs notification on condition that the increase amount of the stored voltage e exceeds a voltage increase amount threshold eith. Note that the storage 36 in this case is an example of a voltage storage unit in the present disclosure.

Operational Effect of Third Embodiment

As described above, the power conversion device 1e according to the third embodiment further includes the storage 36 (resistance value storage unit) that stores, in time series, the resistance value r estimated by the arithmetic unit 32c (resistance value estimator), and the power conversion circuit controller 33d (notifier) performs notification on condition that the increase amount of the resistance value r stored in the storage 36 exceeds the resistance increase amount threshold Rith. This makes it possible to perform early detection and notification of the change in the resistance value (electrical characteristic) of the engagement member B.

In addition, the power conversion device 1e according to the third embodiment further includes the storage 36 (voltage storage unit) that stores, in time series, the voltage e measured by the differential amplifier 31 (voltage measurer), and the power conversion circuit controller 33d (notifier) performs notification on condition that the increase amount of the voltage e stored in the storage 36 exceeds the voltage increase amount threshold eith. This makes it possible to perform early detection and notification of the change in the voltage (electrical characteristic) across the engagement member B.

### Fourth Embodiment

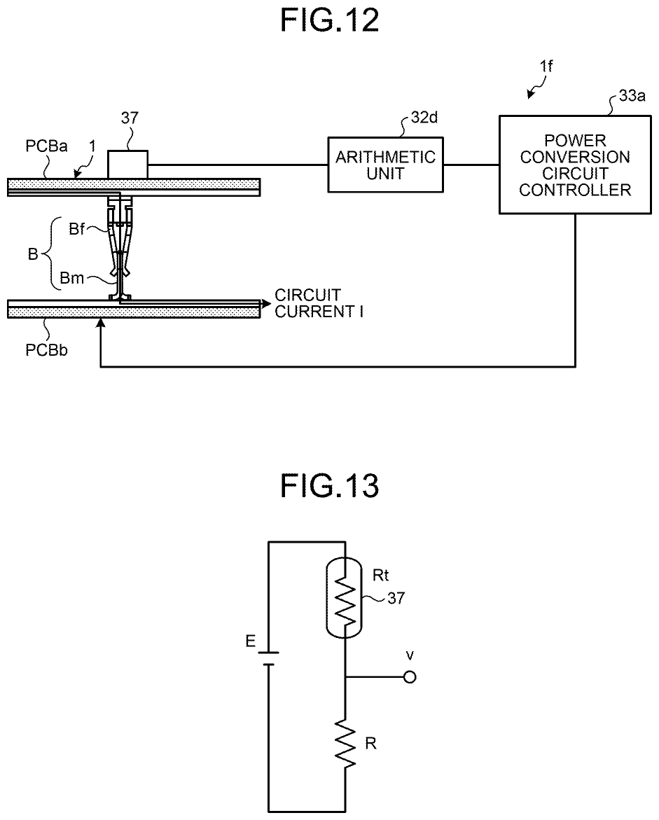

Next, a configuration of a power conversion device 1f according to a fourth embodiment will be described with reference to FIG. 12. FIG. 12 is a block diagram illustrating an example of a schematic configuration of the power conversion device 1f according to the fourth embodiment.

The power conversion device 1f includes a power conversion circuit 1, an arithmetic unit 32d, a power conversion circuit controller 33a, and a temperature sensor 37.

The function of the power conversion circuit 1 is as described above.

The temperature sensor 37 is installed on the circuit board PCBa or the circuit board PCBb, and measures a surface temperature T of the circuit board. An increase in the resistance value r of the engagement member B also increases the surface temperature T of the engagement member B. Therefore, the resistance value r of the engagement member B can be estimated from the surface temperature T of the circuit board PCBa or the circuit board PCBb electrically connected to the engagement member B.

The temperature sensor 37 is, for example, a thermistor. Hereinafter, the temperature sensor 37 is also referred to as a thermistor 37. The thermistor 37 is formed of a substance whose resistance value changes according to the temperature. The thermistor 37 is an example of a state measurer in the present disclosure. The surface temperature T of the circuit board PCBa or the circuit board PCBb is an example of the state of the first component or the second component in the present disclosure.

FIG. 13 is a diagram illustrating an example of a circuit configuration in which temperature is measured by a thermistor. In FIG. 13, an output voltage v obtained by adding an applied voltage E to the circuit is expressed by Formula (1).

v=E×R/(Rt+R) (1)

For example, in the case of using the thermistor 37 in which a resistance value Rt gradually decreases with an increase in temperature, it is desirable to set the value of a resistance value R1 so that the output voltage Eth changes linearly as much as possible in a temperature range to be measured by using a resistance divider circuit illustrated in FIG. 13.

Note that a diode may be used instead of the thermistor 37, for example. A diode has a characteristic that a forward voltage Vf changes according to the temperature when a constant current flows.

The arithmetic unit 32d acquires an output voltage v output from the resistance voltage divider circuit in FIG. 13. In addition, the arithmetic unit 32d converts the acquired output voltage v into a digital value by A/D conversion.

The power conversion circuit controller 33a performs notification on condition that the surface temperature T of the circuit board PCBa or the circuit board PCBb corresponding to the output voltage v exceeds a temperature threshold Tth. Note that the power conversion circuit controller 33a is an example of a notifier in the present disclosure. The temperature threshold Tth is an example of a component state threshold in the present disclosure.

Flow of Processing Performed by Power Conversion Device of Fourth Embodiment

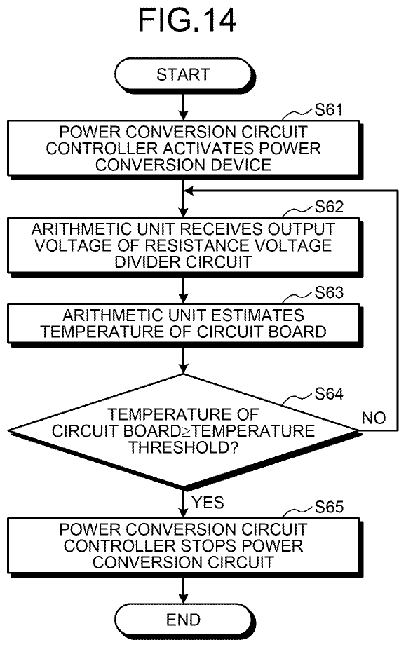

A flow of processing performed by the power conversion device 1f will be described with reference to FIG. 14. FIG. 14 is a flowchart illustrating an example of a flow of processing performed by the power conversion device 1f according to the fourth embodiment.

The power conversion circuit controller 33a activates the power conversion device 1f (Step S61).

The arithmetic unit 32d receives the output voltage v of the resistance voltage divider circuit (Step S62).

The arithmetic unit 32d estimates the surface temperature T of the circuit board from the received output voltage v (Step S63).

The power conversion circuit controller 33a determines whether the surface temperature T of the circuit board is the temperature threshold Tth or more (Step S64). When it is determined that the surface temperature T of the circuit board is the temperature threshold Tth or more (Step S64: Yes), the processing proceeds to Step S65. In contrast, when it is not determined that the surface temperature T of the circuit board is the temperature threshold Tth or more (Step S64: No), the processing returns to Step S62.

When it is determined in Step S64 that the surface temperature T of the circuit board is the temperature threshold Tth or more, the power conversion circuit controller 33a stops the operation of the power conversion circuit 1 (Step S65).

Operational Effect of Fourth Embodiment

As described above, the power conversion device 1f according to the fourth embodiment includes: the circuit board PCBa (first component); the circuit board PCBb (second component); at least one engagement member B configured to engage the male engagement member Bm that is connected to either one of the circuit board PCBa or the circuit board PCBb and that has the conductive and substantially flat plate-shaped insertion portion 11 with the female engagement member Bf that is connected to the other of the circuit board PCBa and the circuit board PCBb and that has the first clamping portion 21 and the second clamping portion 22 having conductivity and disposed to face each other, the engagement of the male engagement member Bm and the female engagement member Bf made by clamping the insertion portion 11 by the first clamping portion 21 and the second clamping portion 22 so as to allow the circuit board PCBa and the circuit board PCBb to be electrically connected to each other; the temperature sensor 37 (state measurer) that measures the surface temperature T of the circuit board PCBa or the circuit board PCBb; and the power conversion circuit controller 33a (notifier) that performs notification on condition that the surface temperature T of the circuit board PCBa or the circuit board PCBb measured by the temperature sensor 37 exceeds the temperature threshold Tth (component state threshold). This makes it possible to perform estimation and notification of the change in the electrical characteristic of the engagement member B based on the change in the physical state of the engagement member B.

In addition, the power conversion device 1f according to the fourth embodiment measures the surface temperature T of the circuit board PCBa (first component) or the circuit board PCBb (second component) as a state of the circuit board PCBa (first component) or the circuit board PCBb (second component). This makes it possible to perform detection and notification of the temperature increase in the engagement member B causing an increase in the contact resistance.

Furthermore, in the power conversion device 1f according to the fourth embodiment, the power conversion circuit controller 33a (notifier) stops energization to the power conversion device 1f on condition that the surface temperature T (state) of the circuit board PCBa (first component) or the circuit board PCBb (second component) measured by the temperature sensor 37 (state measurer) exceeds the temperature threshold Tth (component state threshold). This makes it possible to prevent the power conversion device 1f from being damaged because of a change in an electrical characteristic of the engagement member B.

### Fifth Embodiment

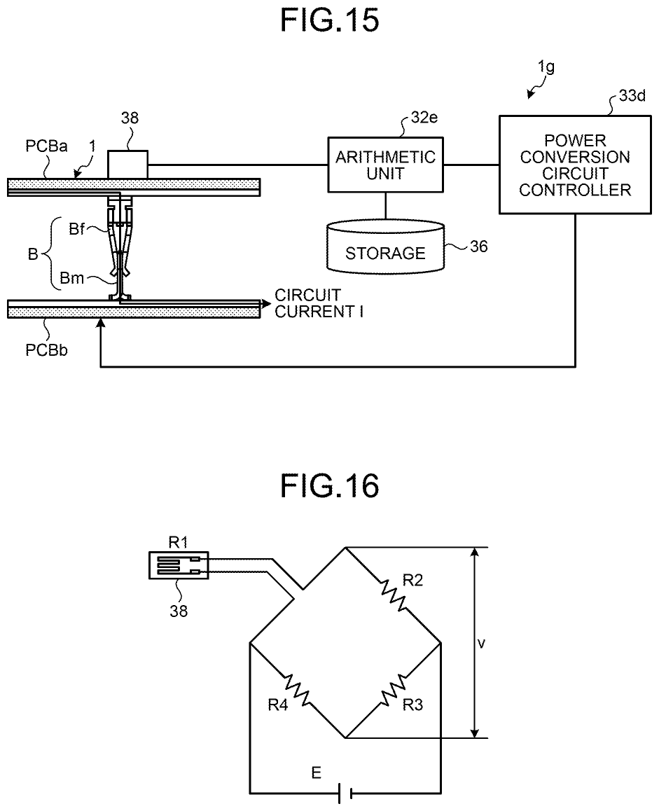

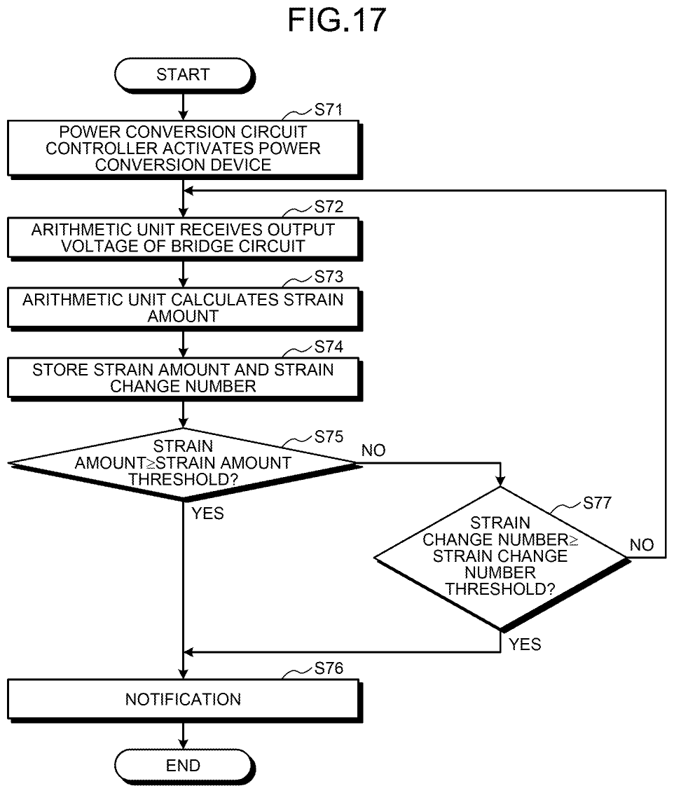

Next, a configuration of a power conversion device 1g according to a fifth embodiment will be described with reference to FIG. 15. FIG. 15 is a block diagram illustrating an example of a schematic configuration of the power conversion device 1g according to the fifth embodiment.

The power conversion device 1g includes a power conversion circuit 1, an arithmetic unit 32e, a power conversion circuit controller 33d, a storage 36, and a strain sensor 38.

The function of the power conversion circuit 1 is as described above.

The strain sensor 38 is installed on the circuit board PCBa or the circuit board PCBb, and measures a strain amount 6 of the circuit board. When a strain occurs in the circuit board, the strain is transmitted to the engagement member B to cause sliding of a contact portion between the male engagement member Bm and the female engagement member Bf. This sliding has a possibility of increasing the resistance value r (contact resistance) of the contact portion of the engagement member B. That is, it is highly possible that the greater a strain amount ε or the larger the strain change number εn, the higher the contact resistance of the engagement member B becomes. Therefore, the resistance value r of the engagement member B can be estimated from the strain amount ε and the strain change number εn in the circuit board PCBa or the circuit board PCBb connected to the engagement member B.

The strain sensor 38 is, for example, a strain gauge. Hereinafter, the strain sensor 38 is also referred to as a strain gauge 38. The strain gauge is a sensor that is bonded to an object to be measured via an insulator and changes its resistance value in accordance with expansion and contraction of the object to be measured. Note that the strain sensor 38 is an example of a state measurer in the present disclosure. The strain amount ε and the strain change number εn in the circuit board PCBa or the circuit board PCBb are examples of states of the first component or the second component in the present disclosure.

FIG. 16 is a diagram illustrating an example of a circuit configuration for measuring strain by a strain gauge. When in use, the strain gauge 38 is typically connected to an electric circuit suitable for detecting a minute resistance change, referred to as a Wheatstone bridge illustrated in FIG. 16. In FIG. 16, it is assumed that the resistance values of a resistor R2, a resistor R3, and a resistor R4 are all equal.

When a resistance value of the strain gauge 38 is R1, a resistance change occurring in the strain gauge 38 by expansion or compression is ΔR1, and a strain amount occurring in the strain gauge 38 is ε, Formula (2) holds.

ΔR1/R1=K×ε (2)

A coefficient K in Formula (2) is a constant of proportionality unique to the strain gauge 38, and is referred to as a gauge factor. In a typical strain gauge, K is approximately 2. When the resistance value R1 of the strain gauge 38 has the resistance change ⊕R1 due to expansion or compression when the bridge circuit of FIG. 16 has an applied voltage E, the output voltage v of the bridge circuit is calculated by Formula (3).

v=(1/4)×(ΔR1/R1)×E (3)

From Formulas (2) and (3), the strain amount ε is obtained by Formula (4).

ε=4×e/(K×E) (4)

The arithmetic unit 32e acquires the output voltage v of the bridge circuit of FIG. 16. The arithmetic unit 32e then converts the acquired output voltage v into a digital value by A/D conversion. In addition, the arithmetic unit 32e calculates the strain amount ε by Formula (4) and calculates the strain change number εn.

The storage 36 stores the strain amount ε calculated by the arithmetic unit 32e and the time at which the strain amount ε is acquired in association with each other. In addition, the storage 36 stores the strain change number εn. Note that the storage 36 is an example of a component state storage unit in the present disclosure.

The power conversion circuit controller 33d reads the strain amount ε and the strain change number εn stored in the storage 36. Subsequently, the power conversion circuit controller 33d performs notification when the stored strain amount ε is larger than a strain amount threshold εth, which is a reference strain amount, or when the strain change number εn is more than a strain change number threshold εnth, which is a reference number of times. The notification may be performed by any method, and may be performed by a display device, an indicator, a buzzer, or example. Note that the power conversion circuit controller 33d is an example of a notifier in the present disclosure. The strain amount threshold εth and the strain change number threshold εnth are examples of the component state threshold in the present disclosure.

Flow of Processing Performed by Power Conversion Device of Fifth Embodiment

A flow of processing performed by the power conversion device 1g will be described with reference to FIG. 15. FIG. 15 is a flowchart illustrating an example of a flow of processing performed by the power conversion device 1g according to the fifth embodiment.

The power conversion circuit controller 33d activates the power conversion device 1g (Step S71).

The arithmetic unit 32e receives the output voltage v of the bridge circuit (Step S72).

The arithmetic unit 32e calculates the strain amount ε from the received output voltage v (Step S73).

The arithmetic unit 32e stores the strain amount ε in the storage 36 in association with the time at which the strain amount ε is measured. In addition, the arithmetic unit 32e stores the strain change number εn in the storage 36 (Step S74).

The power conversion circuit controller 33d determines whether the strain amount ε read from the storage 36 is the strain amount threshold εth or more (Step S75). When it is determined that the strain amount ε is the strain amount threshold εth or more (Step S75: Yes), the processing proceeds to Step S76. In contrast, when it is not determined that the strain amount ε is the strain amount threshold εth or more (Step S75: No), the processing proceeds to Step S77.

When it is not determined in Step S75 that the strain amount ε is the strain amount threshold εth or more, the power conversion circuit controller 33d determines whether the strain change number εn read from the storage 36 is the strain change number threshold εnth or more (Step S77). When it is determined that the strain change number εn is the strain change number threshold εnth or more (Step S77: Yes), the processing proceeds to Step S76. In contrast, when it is not determined that the strain change number εn is the strain change number threshold εnth or more (Step S77: No), the processing returns to Step S72.

When it is determined in Step S75 that the strain amount ε is the strain amount threshold εth or more, or when it is determined in Step S77 that the strain change number εn is the strain change number threshold εnth or more, the power conversion circuit controller 33d performs notification (Step S76).

Operational Effect of Fifth Embodiment

As described above, the power conversion device 1g according to the fifth embodiment measures the strain amount ε or the strain change number εn of the circuit board PCBa (first component) or the circuit board PCBb (second component) as the state of the circuit board PCBa (first component) or the circuit board PCBb (second component). This makes it possible to predict an increase in the contact resistance of the engagement member B connecting the circuit board PCBa and the circuit board PCBb by the strain occurring in the circuit board PCBa or the circuit board PCBb during the operation of the power conversion device 1g.

In addition, the power conversion device 1g according to the fifth embodiment further includes the storage 36 (component state storage unit) that stores, in time series, the strain amount ε and the strain change number εn in the circuit board PCBa (first component) or the circuit board PCBb (second component) measured by the state measurer, and the power conversion circuit controller 33d (notifier) performs notification on condition that the strain amount ε stored in the storage 36 exceeds the strain amount threshold εth or the strain change number εn exceeds the strain change number threshold εnth. This makes it possible to perform early notification of the change in the electrical characteristic of the engagement member B.

### Sixth Embodiment

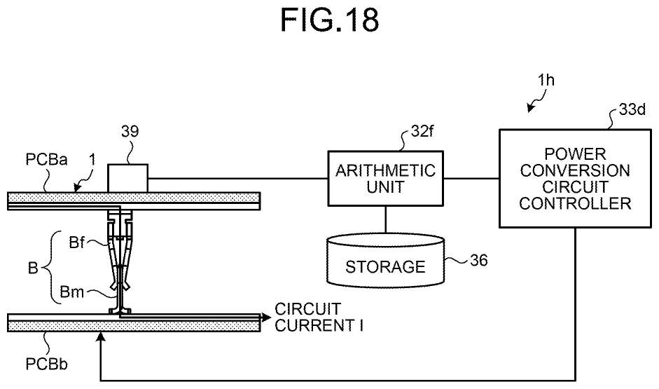

Next, a configuration of a power conversion device 1h according to a sixth embodiment will be described with reference to FIG. 18. FIG. 18 is a block diagram illustrating an example of a schematic configuration of the power conversion device 1h according to the sixth embodiment.

The power conversion device 1h includes a power conversion circuit 1, an arithmetic unit 32f, a power conversion circuit controller 33d, a storage 36, and a vibration sensor 39.

The function of the power conversion circuit 1 is as described above.

The vibration sensor 39 is installed on the circuit board PCBa or the circuit board PCBb, and measures the vibration amplitude M in the circuit board. The vibration generated in the circuit board is transmitted to the engagement member B, and causes sliding of a contact portion between the male engagement member Bm and the female engagement member Bf. This sliding has a possibility of increasing the resistance value r (contact resistance) of the contact portion of the engagement member B. That is, it is highly possible that the larger the vibration amplitude M or the larger the vibration frequency Mn, the higher the contact resistance of the engagement member B becomes. Therefore, the resistance value r of the engagement member B can be estimated from the vibration amplitude M and the vibration frequency Mn of the circuit board PCBa or the circuit board PCBb connected to the engagement member B.

The vibration sensor 39 is an acceleration sensor, for example. The acceleration sensor detects generated acceleration using a piezoelectric device (piezoelectric element) that generates a voltage according to the applied pressure, for example. The voltage generated according to the pressure can be calculated by measuring a current flowing when the voltage is applied to a resistor having a known resistance value. Note that the vibration sensor 39 is an example of a state measurer in the present disclosure. The vibration amplitude M and the vibration frequency Mn in the circuit board PCBa or the circuit board PCBb are examples of the states of the first component or the second component in the present disclosure.

The arithmetic unit 32f acquires the current corresponding to data obtained by the measurement of the vibration sensor 39, for example, corresponding to the voltage output from the vibration sensor 39. The arithmetic unit 32f then converts the acquired current into a digital value by A/D conversion. In addition, the arithmetic unit 32f calculates the vibration frequency Mn based on the change amount of the current output from the vibration sensor 39.

The storage 36 stores the current value acquired by the arithmetic unit 32f (or the vibration amplitude M estimated from the current value) and the time at which the current value is acquired in association with each other. In addition, the storage 36 stores the vibration frequency Mn. Note that the storage 36 is an example of a component state storage unit in the present disclosure.

The power conversion circuit controller 33d reads the current value (or the vibration amplitude M) and the vibration frequency Mn stored in the storage 36. Subsequently, the power conversion circuit controller 33d performs notification when the vibration amplitude M is larger than a vibration amplitude threshold Mth, which is a reference vibration amplitude, or when the vibration frequency Mn is more than a vibration frequency threshold Mnth, which is a reference number of times. The notification may be performed by any method, and may be performed by a display device, an indicator, a buzzer, or example. Note that the power conversion circuit controller 33d is an example of a notifier in the present disclosure. The vibration amplitude threshold Mth and the vibration frequency threshold Mnth are examples of the component state threshold in the present disclosure.

Flow of Processing Performed by Power Conversion Device of Sixth Embodiment

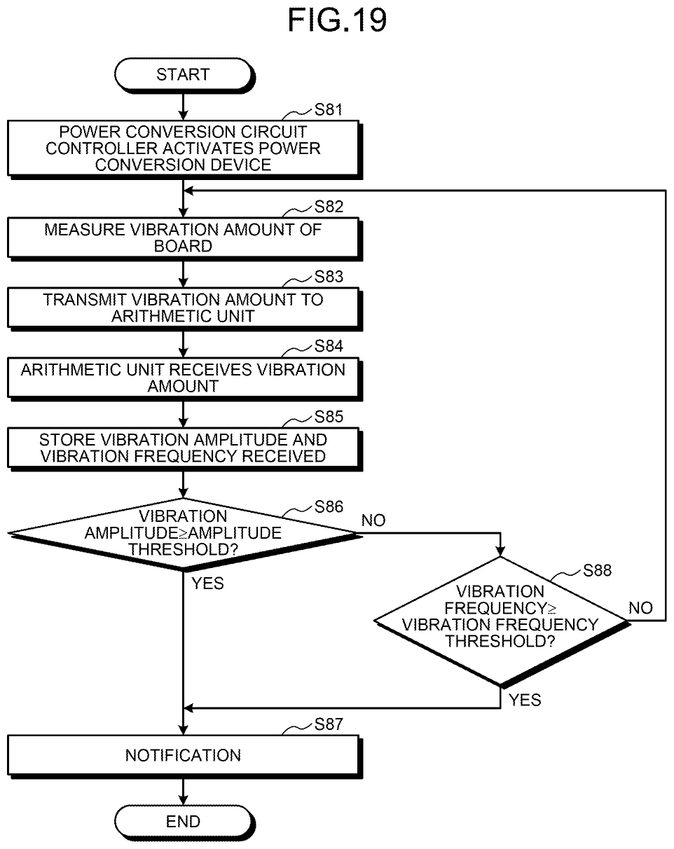

A flow of processing performed by the power conversion device 1h will be described with reference to FIG. 19. FIG. 19 is a flowchart illustrating an example of a flow of processing performed by the power conversion device 1h according to the sixth embodiment.

The power conversion circuit controller 33d activates the power conversion device 1h (Step S81).

The vibration sensor 39 measures a vibration amount (vibration amplitude M) regarding the vibration of the circuit board (Step S82).

The vibration sensor 39 transmits the measured vibration amplitude M (current corresponding to the voltage output from the vibration sensor 39) to the arithmetic unit 32f (Step S83).

The arithmetic unit 32f receives, from the vibration sensor 39, the vibration amplitude M (current corresponding to the voltage output from the vibration sensor 39) (Step S84).

The arithmetic unit 32f stores the vibration amplitude M (current corresponding to the voltage output from the vibration sensor 39) in the storage 36 in association with the time at which the vibration amplitude M is measured. In addition, the arithmetic unit 32f stores the vibration frequency Mn in the storage 36 (Step S85).

The power conversion circuit controller 33d determines whether the vibration amplitude M read from the storage 36 is the vibration amplitude threshold Mth or more (Step S86). When it is determined that the amplitude M is the vibration amplitude threshold Mth or more (Step S86: Yes), the processing proceeds to Step S87. In contrast, when it is not determined that the vibration amplitude M is the vibration amplitude threshold Mth or more (Step S86: No), the processing proceeds to Step S88.

When it is not determined in Step S86 that the vibration amplitude M is the vibration amplitude threshold Mth or more, the power conversion circuit controller 33d determines whether the vibration frequency Mn read from the storage 36 is the vibration frequency threshold Mnth or more (Step S88). When it is determined that the vibration frequency Mn is the vibration frequency threshold Mnth or more (Step S88: Yes), the processing proceeds to Step S87. In contrast, when it is not determined that the vibration frequency Mn is the vibration frequency threshold Mnth or more (Step S88: No), the processing returns to Step S82.

When it is determined in Step S86 that the vibration amplitude M is the vibration amplitude threshold Mth or more, or when it is determined in Step S88 that the vibration frequency Mn is the vibration frequency threshold Mnth or more, the power conversion circuit controller 33d performs notification (Step S87).

Operational Effect of Sixth Embodiment

As described above, the power conversion device 1h according to the sixth embodiment measures the vibration amplitude M or the vibration frequency Mn of the circuit board PCBa (first component) or the circuit board PCBb (second component) as the state of the circuit board PCBa (first component) or the circuit board PCBb (second component). This makes it possible to predict an increase in the contact resistance of the engagement member B connecting the circuit board PCBa and the circuit board PCBb by the vibration occurring in the circuit board PCBa or the circuit board PCBb during the operation of the power conversion device 1h.

According to the power conversion device of the present disclosure, it is possible to estimate a change in an electrical characteristic of an engagement member in the power conversion device that has a connection structure in which different circuit boards are connected by the conductive engagement member.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A power conversion device comprising:
a first component;
a second component;
at least one engagement member configured to engage a male engagement member with a female engagement member to allow the first component and the second component to be electrically connected to each other, the male engagement member being connected to one of the first component and the second component and having a conductive and substantially flat plate-shaped insertion portion, the female engagement member being connected to another of the first component and the second component and having conductive first and second clamping portions disposed to face each other, and the engagement of the male engagement member and the female engagement member being made by clamping the insertion portion by the first and second clamping portions;
a voltage measurer configured to measure a voltage across the at least one engagement member;
a resistance value estimator configured to estimate a resistance value of the engagement member based on the voltage measured by the voltage measurer; and
a notifier configured to perform notification on condition that the resistance value estimated by the resistance value estimator exceeds a resistance threshold.

2. The power conversion device according to claim 1, wherein
the resistance value estimator is configured to estimate the resistance value of the engagement member based on the voltage measured by the voltage measurer and a current command value flowing between the first component and the second component.

3. The power conversion device according to claim 1, further comprising:
a current measurer configured to measure a current flowing through the engagement member, wherein
the resistance value estimator is configured to estimate the resistance value of the engagement member based on the voltage measured by the voltage measurer and the current measured by the current measurer.

4. The power conversion device according to claim 1, further comprising:
a resistance value storage unit configured to store, in time series, the resistance value estimated by the resistance value estimator, wherein
the notifier is configured to perform notification on condition that an increase amount of the resistance value stored in the resistance value storage unit exceeds a resistance increase amount threshold.

5. The power conversion device according to claim 2, further comprising:
a resistance value storage unit configured to store, in time series, the resistance value estimated by the resistance value estimator, wherein
the notifier is configured to perform notification on condition that an increase amount of the resistance value stored in the resistance value storage unit exceeds a resistance increase amount threshold.

6. The power conversion device according to claim 3, further comprising:
a resistance value storage unit configured to store, in time series, the resistance value estimated by the resistance value estimator, wherein
the notifier is configured to perform notification on condition that an increase amount of the resistance value stored in the resistance value storage unit exceeds a resistance increase amount threshold.

7. The power conversion device according to claim 1, wherein
the notifier is configured to stop the power conversion device on condition that the resistance value estimated by the resistance value estimator exceeds the resistance threshold.

8. The power conversion device according to claim 2, wherein
the notifier is configured to stop the power conversion device on condition that the resistance value estimated by the resistance value estimator exceeds the resistance threshold.

9. The power conversion device according to claim 3, wherein
the notifier is configured to stop the power conversion device on condition that the resistance value estimated by the resistance value estimator exceeds the resistance threshold.

10. The power conversion device according to claim 4, wherein
the notifier is configured to stop the power conversion device on condition that the resistance value estimated by the resistance value estimator exceeds the resistance threshold.

11. A power conversion device comprising:
a first component;
a second component;
at least one engagement member configured to engage a male engagement member with a female engagement member to allow the first component and the second component to be electrically connected to each other, the male engagement member being connected to one of the first component and the second component and having a conductive and substantially flat plate-shaped insertion portion, the female engagement member being connected to another of the first component and the second component and having conductive first and second clamping portions disposed to face each other, and the engagement of the male engagement member and the female engagement member being made by clamping the insertion portion by the first and second clamping portions;
a voltage measurer configured to measure a voltage across the engagement member; and
a notifier configured to perform notification on condition that the voltage measured by the voltage measurer exceeds a voltage threshold.

12. The power conversion device according to claim 11, wherein
the voltage threshold is a voltage across the engagement member when a maximum current estimated to flow through the power conversion device flows through the engagement member in a case where the engagement member is assumed to have a predetermined reference resistance value.

13. The power conversion device according to claim 11, further comprising:
a voltage storage unit configured to store, in time series, the voltage measured by the voltage measurer, wherein
the notifier is configured to perform notification on condition that an increase amount of the voltage stored in the voltage storage unit exceeds a voltage increase amount threshold.

14. The power conversion device according to claim 11, wherein
the notifier is configured to stop the power conversion device on condition that the voltage measured by the voltage measurer exceeds the voltage threshold.

15. A power conversion device comprising:
a first component;
a second component;
at least one engagement member configured to engage a male engagement member with a female engagement member to allow the first component and the second component to be electrically connected to each other, the male engagement member being connected to one of the first component and the second component and having a conductive and substantially flat plate-shaped insertion portion, the female engagement member being connected to another of the first component and the second component and having conductive first and second clamping portions disposed to face each other, and the engagement of the male engagement member and the female engagement member being made by clamping the insertion portion by the first and second clamping portions;
a state measurer configured to measure a state of the first component or the second component; and
a notifier configured to perform notification on condition that the state of the first component or the second component measured by the state measurer exceeds a component state threshold.

16. The power conversion device according to claim 15, wherein
the state is a temperature of the first component or the second component.

17. The power conversion device according to claim 15, wherein
the state is a strain amount or a strain change number in the first component or the second component.

18. The power conversion device according to claim 15, wherein
the state is a vibration amplitude or a vibration frequency of the first component or the second component.

19. The power conversion device according to claim 15, further comprising:
a component state storage unit configured to store, in time series, the state of the first component or the second component measured by the state measurer, wherein
the notifier is configured to perform notification on condition that the state of the component stored in the component state storage unit exceeds the component state threshold.

20. The power conversion device according to claim 15, wherein
the notifier is configured to stop the power conversion device on condition that the state of the first component or the second component measured by the state measurer exceeds the component state threshold.
